(19) United States
(12) Patent Application Publication
(10) Pub. No.: US 2024/0395567 A1
(43) Pub. Date: Nov. 28, 2024

(54) SELECTIVE UNDERFILLING USING PRE-APPLIED THERMOSET ADHESIVE

(71) Applicant: Intel Corporation, Santa Clara, CA (US)

(72) Inventors: Jonas G. Croissant, Maricopa, AZ (US); Yiqun Bai, Chandler, AZ (US); Dingying Xu, Chandler, AZ (US); Xavier F. Brun, Hillsboro, OR (US); Timothy Gosselin, Phoenix, AZ (US); Ye Seul Nam, Chandler, AZ (US); Gustavo Arturo Beltran, Chandler, AZ (US); Roberto Serna, Chandler, AZ (US); Jesus S. Nieto Pescador, Chandler, AZ (US); Aris Mercado Orbase, Chandler, AZ (US)

(73) Assignee: Intel Corporation, Santa Clara, CA (US)

(21) Appl. No.: 18/323,521

(22) Filed: May 25, 2023

(51) Int. Cl. H01L 21/56; G02B 6/122; H01L 23/00; H01L 23/31; H01L 23/48; H01L 23/498

(52) U.S. Cl. CPC H01L 21/563; G02B 6/122; H01L 23/3128; H01L 23/481; H01L 23/49816; H01L 24/81; H01L 24/83; G02B 2006/12121; H01L 2224/81203; H01L 2224/8385; H01L 2924/12042

(57) ABSTRACT

Integrated circuit (IC) packages with pre-applied underfill in select areas, and methods of forming the same, are disclosed herein. In one example, an IC package includes a package substrate, a first IC die electrically coupled to the package substrate, a second IC die electrically coupled to the first IC die, and a thermoset adhesive that partially fills an area between the first IC die and the second IC die.

### BACKGROUND

High-speed optical interconnects are crucial to meet the continuously increasing data rate demands of modern data centers and computing systems. Due to design constraints, however, packaging traditional computing components with optical transceivers can be challenging. For example, the design rules for an optical package may define various keep out zones (KOZs) that must remain free of underfill and other obstructions, such as areas where the package emits laser beams or interfaces with other optical components. Existing underfill processes are unable to satisfy these design rules, however, as they are unable to keep underfill material out of the restricted areas.

### BRIEF DESCRIPTION OF THE DRAWINGS

FIGS. 1A-B illustrate an example embodiment of an optical package with pre-applied underfill.

FIGS. 2A-E illustrate an optical packaging process using pre-applied thermoset adhesive.

FIG. 3 illustrates an example of the unique geometry of pre-applied thermoset adhesive underfill.

FIG. 4 illustrates an example cross-section image of a joint between two dies bonded together using thermoset adhesive.

FIG. 5 illustrates a flowchart for a pre-applied underfill and chip attach process using thermoset adhesive.

FIGS. 6A-B illustrate an example embodiment of an optical package in accordance with certain embodiments.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIG. 9 is a cross-sectional side view of an integrated circuit device assembly that may include a microelectronic assembly, in accordance with any of the embodiments disclosed herein.

FIG. 10 is a block diagram of an example electronic device that may include a microelectronic assembly, in accordance with any of the embodiments disclosed herein.

### DETAILED DESCRIPTION

High-speed optical interconnects are crucial to meet the continuously increasing data rate demands of modern data centers and computing systems. For example, by packaging traditional computing components (e.g., processors, accelerators, FPGAs, switches, memory/storage, other ASIC nodes) with optical transceivers, those components can communicate over high-speed optical interconnects rather than traditional electrical interconnects.

Due to design constraints, however, there are various challenges associated with optical packaging. For example, an optical package typically includes an electronic integrated circuit (EIC) and a photonic integrated circuit (PIC). The EIC is used to control the PIC and interface with other electronic components, while the PIC is used to send and receive optical signals over an array of fibers. Moreover, the design rules for an optical package may define various keep out zones (KOZs), which are restricted areas that must remain unused or are otherwise subject to certain restrictions. For example, an optical package may have certain KOZs that must remain free of underfill and other obstructions, such as areas where the PIC emits laser beams or contains grooves (e.g., V-grooves) to interface with an optical coupler and/or fiber array. As a result, the optical packaging process requires selective underfilling of chiplets to prevent the underfill material from flowing to restricted areas (e.g., the laser or V-groove areas of the PIC).

Existing underfill processes are unsuitable for these optical packaging design rules. For example, traditional capillary underfill (CUF) processes are only capable of filling the entire area under a chip—they are unable to control the underfill flow location. Further, the use of chemical barriers to prevent underfill material from flowing outside the intended area—and into the KOZs—is not a feasible solution. For example, the barriers would have to be 100% leak proof at the chip gap level, as even the slightest gap (e.g., 10×20 μm) can result in massive leaks of underfill material in the restricted areas. As a result, if the barrier is too short, leaking may occur. However, if the barrier is too tall to prevent leaks, it may prevent the joints from bonding between the PIC and the EIC.

Other underfill processes suffer from similar limitations. For example, thermocompression bonding using non-conductive film (TC-NCF) requires an entire wafer to be covered with non-conductive film—it does not have selective underfill capabilities to prevent the film from being applied to restricted areas on the wafer. The same limitations apply to mold underfill (MUF) processes.

Accordingly, this disclosure presents embodiments of a selective underfill process using pre-applied thermoset adhesive, and integrated circuit packages formed using the same. The described embodiments enable the underfill location to be controlled using a pre-applied thermoset adhesive, which is strategically dispensed on a chip or substrate (e.g., at targeted locations using customized patterns and shot weights) such that, when compressed, the adhesive expands or spreads only into the intended underfill areas while the restricted areas remain free of underfill. In this manner, the described embodiments can be used to selectively fill the space below a PIC with underfill only in the intended areas (e.g., where the conductive contacts reside), while keeping the laser and V-groove areas free of underfill, thus maintaining the performance and reliability of the laser and optical components of the PIC.

These embodiments provide various advantages. For example, the selective underfill process enables fabrication of advanced packages with restricted areas, such as optical packages. This process is highly flexible and can be applied to any type of package with restricted area design rules, as the selective underfilling can be tailored to target intended areas and avoid restricted areas of any geometry (e.g., by dispensing the appropriate pattern and shot weight of underfill material at the appropriate location(s)).

Unlike traditional capillary underfill (CUF) processes, this selective underfill process keeps underfill out of restricted areas without use of a chemical barrier, thus avoiding the potential complications that may arise when using chemical barriers. Further, unlike CUF processes, this process prevents the underfill from forming an upward fillet that can contaminate the V-groove area of the PIC and cause reliability failures.

Moreover, because the thermoset underfill is pre-applied (e.g., applied before the chip is attached rather than after), the underfill material is cured simultaneously during the chip attach process using thermocompression bonding (TCB) (e.g., compression of the chip and underfill material at high temperatures). As a result, this process eliminates the separate step of curing the underfill material after performing the chip attach, which is required by many existing processes (e.g., capillary underfill processes).

Accordingly, since this underfill process does not require a chemical barrier to protect the restricted area/KOZ, nor a separate post-chip-attach underfill cure step, it is faster, easier, and cheaper than existing processes (e.g., processes such as CUF that require a separate post-chip-attach underfill cure step and/or a barrier cure step).

This underfill process is also effective at fine pitch (e.g., for semiconductor devices with a high concentration of conductive leads, such as bumps, balls, pads, etc.).

Further, this process has advantages even for packages that do not have restricted areas, including the efficiencies from eliminating the post-chip-attach underfill cure step (e.g., cost and time savings), and its efficacy at fine pitch, among other examples.

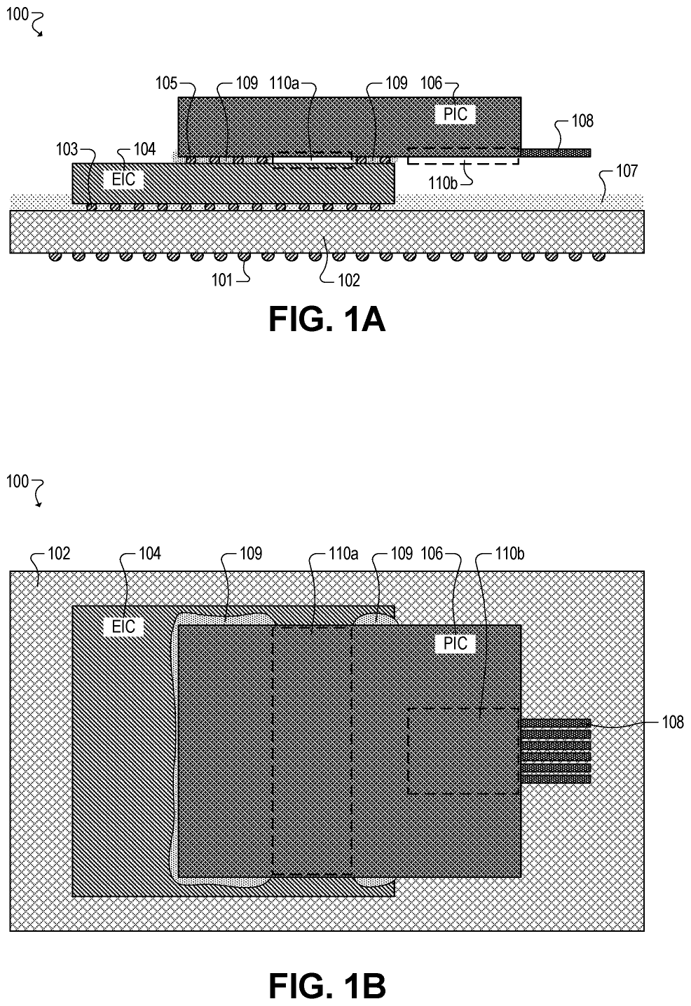

FIGS. 1A-B illustrate an example embodiment of an optical package 100 with pre-applied underfill in select areas. In the illustrated example, cross-section and plan views of optical package 100 are respectively shown in FIGS. 1A and 1B.

In the illustrated embodiment, the optical package 100 includes an electronic integrated circuit (EIC) 104 and a photonic integrated circuit (PIC) 106 on a package substrate 102. The EIC 104 is electrically coupled to the top surface of the package substrate 102, and the PIC 106 is electrically coupled to the top surface of the EIC 104. The EIC 104 is used to control the PIC 106, and the PIC 106 is used to send and receive optical signals over an array of optical fibers 108.

Further, the PIC 106 is designed to emit laser beams through an area 110a between the PIC 106 and the EIC 104, and the PIC 106 also includes an overhang area 110b with features such as V-grooves (not shown) to optically couple the PIC 106 with an array of optical fibers 108 (e.g., either directly or indirectly via an optical coupler/connector). The laser and V-groove areas 110a-b must remain unobstructed to maintain the performance and reliability of the laser and other optical components of the PIC 106.

As a result, the design rules for the optical package 100 may define the laser and V-groove areas 110a-b as restricted areas, or keep out zones (KOZs), that must remain free obstructions, such as underfill. However, the design rules may also require the space below the PIC 106 to be filled with underfill 109 around the conductive contacts 105 to protect the electrical connections between the PIC 106 and EIC 104.

Based on these competing design rules, the space below the PIC 106 must be selectively filled with underfill 109 in areas where the conductive contacts 105 are located, but not in the restricted areas 110a-b near the laser and V-grooves of the PIC 106. Existing underfill processes are unable to satisfy these design rules, however, as they cannot control or restrict the flow location of underfill.

Accordingly, in the illustrated embodiment, optical package 100 is formed using a selective underfill process with pre-applied thermoset adhesive 109, which enables the underfill location to be controlled. For example, before the PIC 106 is attached, a thermoset adhesive 109 is strategically pre-applied to the surface of the EIC 104 at targeted locations using customized patterns and shot weights. The PIC 106 is then attached to the EIC 104 using thermocompression bonding (TCB) by placing the PIC 106 on the EIC 104 and compressing them at high temperature (e.g., applying pressure/force and heat simultaneously). As a result, the thermoset adhesive 109 is compressed between the PIC 106 and EIC 104, which causes it to spread or flow into the intended areas—but not the restricted areas 110a-b—due to the strategically chosen locations, patterns, and shot weights of the pre-applied adhesive 109. In some cases, this may result in a cavity, hollow area, or gap in a restricted area, such as the restricted laser area 110a, without the presence of a physical barrier.

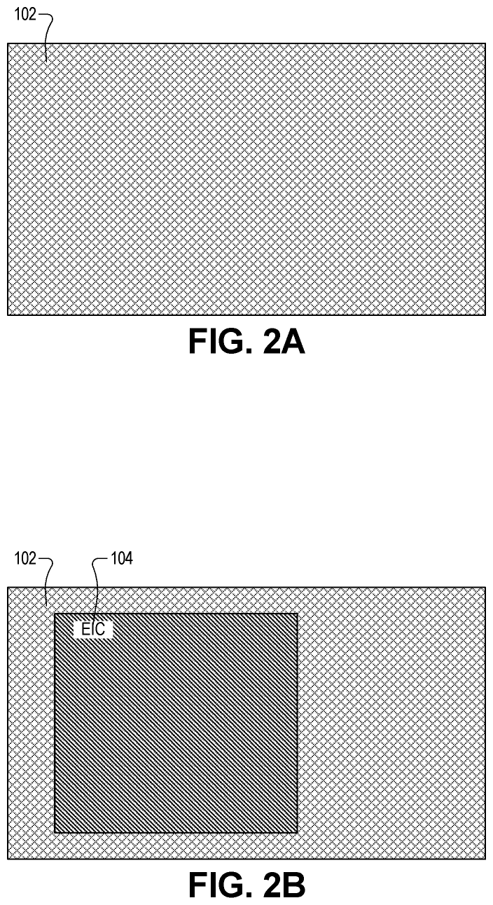

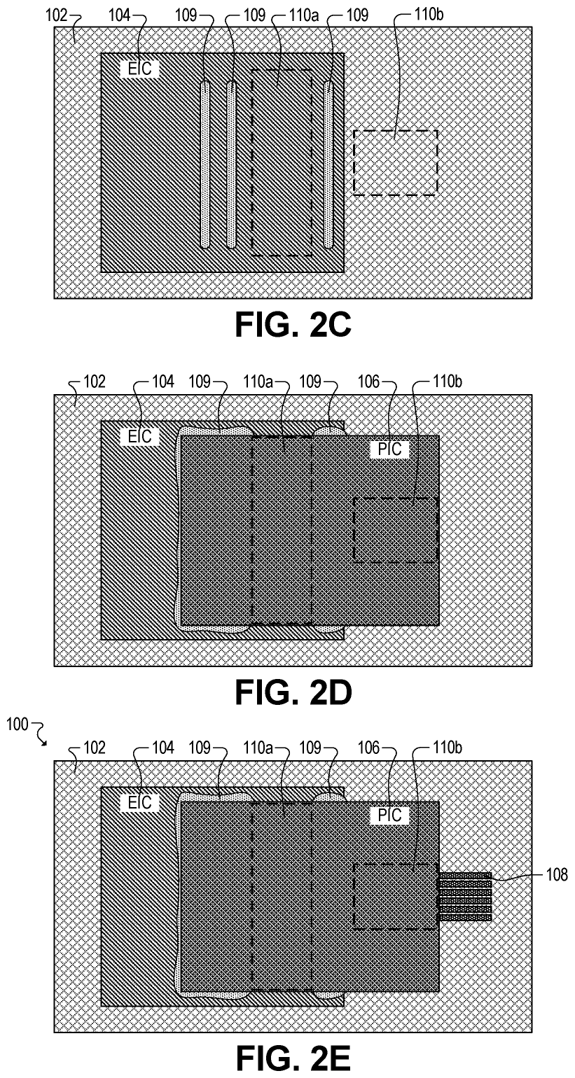

In this manner, the space below the PIC 106 is selectively filled with underfill 109 in the intended areas where the conductive contacts 105 reside, but not in the restricted areas 110a-b near the laser and V-grooves, thus protecting the electrical connections 105 between the PIC 106 and EIC 104 without degrading the performance and reliability of the laser and other optical components of the PIC 106. The selective underfill process is described further in connection with FIGS. 2A-E.

The adhesive 109 may be made of any suitable material(s) that are adhesive, viscous, and non-conductive, such as those described throughout this disclosure. In some embodiments, for example, the adhesive 109 may be a thermoset adhesive that cures when exposed to heat or radiation (e.g., thermal or ultraviolet (UV) curing), such as a thermosetting polymer. For example, in some embodiments, the adhesive 109 may be a non-conductive paste (NCP) made of an acrylic polymer with silica filler. In other embodiments, however, the adhesive 109 may be made of material(s) that are curable using other (e.g., non-thermal) curing processes.

Turning back to the components of optical package 100, the package substrate 102 includes conductive contacts 101 (e.g., metal balls, bumps, micro-bumps) on the bottom surface, which serve as a second level interconnect (SLI) to a next-level component, such as a printed circuit board (e.g., a motherboard) and/or another integrated circuit package (not shown). The package substrate 102 also includes conductive traces (not shown) patterned in the substrate to provide power and input/output (I/O) to the respective components in package 100 (e.g., EIC 104, PIC 106). The top surface of the package substrate 102 is coated with die attach film 107, which is an adhesive used to attach the EIC 104 and potentially other components (not shown) to the package substrate 102.

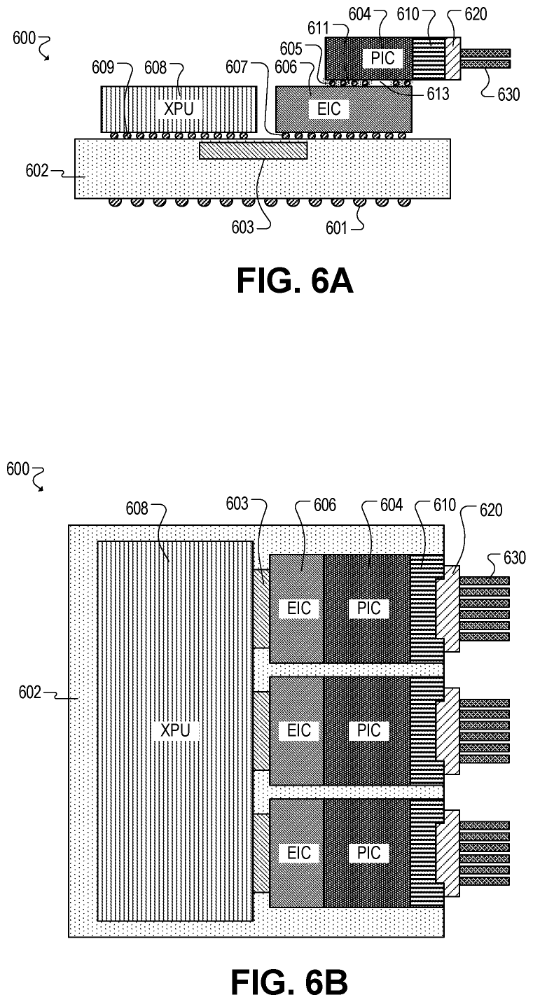

The EIC 104 is attached to the top surface of the package substrate 102 via the die attach film 107, and the EIC 104 is electrically coupled to the package substrate 102 via conductive contacts 103 on their respective surfaces (e.g., metal balls, bumps, micro-bumps, pads). The EIC 104 may include any suitable electronic components and circuitry for controlling the PIC 106 (e.g., the components described in connection with the EICs 606 of FIGS. 6A-B).

The PIC 106 is attached to the top surface of the EIC 104 via thermoset adhesive 109 (e.g., as described above), and the PIC 106 is electrically coupled to the EIC 104 via conductive contacts 105 on their respective surfaces (e.g., metal balls, bumps, micro-bumps, pads). The PIC 106 may include any suitable photonic components and circuitry for sending and receiving optical signals (e.g., the components described in connection with the PICs 604 of FIGS. 6A-B).

Further, the PIC 106 is optically coupled to a fiber array 108 (either directly or indirectly via an optical connector), which enables the PIC 106 to send and receive optical signals to and from other components (not shown). For example, the other end of the fiber array 108 may be optically coupled to other components (not shown), such as other computing components that are part of the same device or system as optical package 100 (e.g., processors, XPUs, network interface controllers (NICs), storage, memory, I/O devices, other integrated circuits), an external device or system, a switch, an optical connector, a fiber cable, and so forth.

It should be appreciated that optical package 100 is merely presented as an example. In other embodiments, certain components may be omitted, added, rearranged, modified, or combined. For example, embodiments may include any number, combination, or arrangement of EICs and PICS (e.g., for higher bandwidth and/or redundancy), optical connectors, optical couplers, optical ferrules, optical interposers, fibers, bridges, XPUs or other computing components, substrates, surface cavities in the substrate, conductive contacts, conductive traces, vias, integrated circuit packages, and so forth.

In various embodiments, for example, the PIC may be above or below the EIC, or the PIC and EIC may be adjacent to each other on a substrate, and the thermoset adhesive may be pre-applied on either the PIC or the EIC. Pre-applied thermoset adhesive may also be used for attaching and underfilling other components (e.g., attaching an IC die to the package substrate, or attaching other IC dies to each other). Moreover, while the EIC is used to control the PIC in the illustrated embodiment, the EIC may be any type of electronic integrated circuit in other embodiments (e.g., processor, XPU, etc.). Further, in some embodiments, other computing components may be co-packaged with optical package 100 (e.g., processors, CPUs, XPUs, memory, storage, NICs, I/O devices), either on the same or different package substrate.

FIGS. 2A-E illustrate an example optical packaging process using pre-applied thermoset adhesive. In the illustrated embodiment, the optical packaging process is used to form optical package 100 of FIGS. 1A-B.

In FIG. 2A, the packaging process begins by receiving a substrate coated in an adhesive, such as a glass substrate with die attach film on the surface.

In FIG. 2B, an electronic integrated circuit (EIC) 104 is attached to the surface of the substrate 102 via the adhesive, and the EIC 104 and substrate 102 are electrically coupled via conductive contacts (not shown) on their respective surfaces.

In FIG. 2C, thermoset adhesive 109 is dispensed on the surface of the EIC 104 in select locations, patterns, and shot weights (e.g., using an automated dispenser). In the illustrated embodiment, for example, multiple lines of the adhesive 109 are dispensed on the EIC 104 in areas where electrical connections will be formed between the EIC 104 and a subsequently attached a photonic integrated circuit (PIC) 106. However, the lines of the adhesive 109 are all outside the keep out zones (KOZs) 110a-b defined by the design rules for the optical package 100. In this manner, when the PIC 106 is subsequently attached to the EIC 104, the adhesive 109 will be compressed, causing it to spread into the intended areas where the electrical connections reside while remaining outside the restricted KOZs 110a-b.

The resulting underfill footprint is based on the optimized location, pattern, and shot weight of the pre-applied thermoset adhesive 109. For example, the thermoset adhesive 109 is a viscous adhesive with a no-flow profile (e.g., a non-conductive paste (NCP)), which allows it to be dispensed in precise locations on a die or substrate for KOZ control (e.g., selectively dispensing the adhesive 109 in desired underfill areas and outside any restricted areas).

The thermoset adhesive 109 can also be dispensed in a variety of patterns to achieve the appropriate underfill profile once compressed, including, without limitation, lines (straight or curved), dot-like patterns, star-like patterns, squares, rectangles, circles, and combinations thereof. For example, dispensing a single line or multiple parallel lines in close proximity may result in a compressed underfill profile with a roughly oval shape or rectangular shape with rounded corners. More complex patterns can be used for more complex underfill profiles with varying shapes (e.g., oval, circle, square, rectangle, L-shape, etc.).

The shot weight refers to the amount (e.g., mass) of adhesive 109 dispensed. The shot weight can be tuned to control the extent to which the adhesive 109 spreads when compressed (e.g., the shot weight can be increased/decreased to increase/decrease the size of the compressed underfill footprint). Further, the shot weight may vary for different locations and/or patterns within a given application (e.g., the adhesive may be dispensed in location A with pattern B and shot weight C, and the adhesive may also be dispensed in location X with pattern Y and shot weight Z).

In this manner, the location, pattern, and shot weight of the adhesive 109 can be tuned for different applications and design rules to achieve the appropriate underfill profile.

The adhesive 109 may be made of any suitable material(s) that are adhesive, viscous, and non-conductive, such as a thermoset adhesive or thermosetting polymer cured using heat or radiation. In some embodiments, for example, the adhesive may be a non-conductive paste (NCP) made of an organic polymer and optionally an inorganic filler, such as an acrylic polymer with silica filler.

In FIG. 2D, the PIC 106 is attached to the EIC 104 using thermocompression bonding (TCB).

For example, the PIC 106 is placed on the EIC 104 with their respective conductive contacts aligned, and the PIC 106 and EIC 104 are then compressed together at high temperature (e.g., applying pressure/force and heat simultaneously). As a result, the thermoset adhesive 109 is compressed between the PIC 106 and EIC 104, which causes it to spread or flow into the intended areas—but not the restricted areas 110a-b—due to the strategically chosen locations, patterns, and shot weights of the pre-applied adhesive 109 from FIG. 2C.

In this manner, the space below the PIC 106 is selectively filled with underfill 109 in the intended areas where the conductive contacts 105 reside, but not in the restricted areas 110a-b near the laser and V-grooves, thus protecting the electrical connections 105 between the PIC 106 and EIC 104 without degrading the performance and reliability of the laser and other optical components of the PIC 106. Further, the heat cures the compressed thermoset adhesive 109, which bonds the PIC 106 to the EIC 104.

The compressive force and heat also cause the formation of joints, or electrical connections, between the conductive contacts on the PIC 106 and the EIC 104. In some embodiments, a compression force of approximately 30 Kg may provide a proper bump collapse.

In FIG. 2E, a fiber array 108 (e.g., a bundle of glass fibers) is optically coupled with the PIC 106 either directly (e.g., via adhesive) or indirectly (e.g., via an optical connector). In some embodiments, for example, the fibers 108 may be attached directly to the V-grooves in the PIC 106 using an adhesive. Alternatively, an optical ferrule (not shown) may be attached to the fibers 108, an optical coupler (not shown) may be attached to the V-grooves in the PIC 106, and the optical ferrule and optical coupler may be designed to interface with each other (e.g., by plugging one into the other).

While the illustrated example depicts the packaging process for an individual optical package, the same packaging process may be implemented at the wafer or panel level for high-volume manufacturing of optical packages. For example, the EICs and PICs may be separately fabricated and singulated, the EICs may be reconstituted onto a glass wafer or panel coated with an adhesive, the PICs may be attached to corresponding EICs using pre-applied thermoset adhesive (e.g., as described above), and the wafer or panel may then be singulated to separate the resulting optical packages.

Further, a similar packaging process may be used for any other type of integrated circuit package (e.g., for attaching/underfilling IC dies or packages on other dies, packages, substrates, circuit boards, etc.).

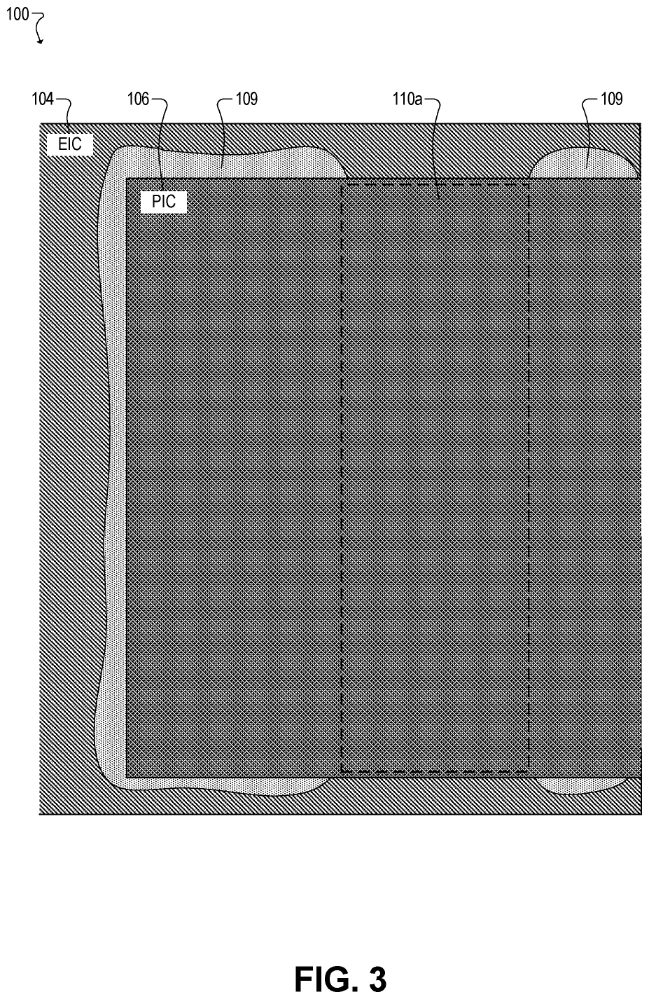

FIG. 3 illustrates an example of the unique geometry of pre-applied thermoset adhesive underfill in an optical package. In particular, a magnified top-view perspective is shown for a portion of optical package 100 (e.g., from FIGS. 1B and 2E), which depicts the unique and irregular geometry of the pre-applied thermoset adhesive underfill 109. During thermocompression bonding (TCB) processing to attach the PIC 106 to the EIC 104, compression of the adhesive 109 causes it to flow out from under the chiplet, which yields a unique geometry. In some embodiments, for example, the adhesive 109 may flow out from under the PIC 106 by approximately 300-400 μm depending on the shot weight. As a result, the edges of the adhesive 109 extend beyond the PIC 106 edges by varying distances, thus forming an asymmetrical underfill footprint with irregular, non-uniform curved edges, as opposed to a symmetrical footprint with straight edges (e.g., a rectangle or square). In addition, a fillet is formed at the edges of the adhesive 109 where it flows out from under the PIC 106. Due to the location, pattern and shot weight of the pre-applied thermoset adhesive 109, however, the compressed adhesive 109 does not spread into the laser KOZ 110a, which is an area (e.g., approximately 3000×9000 μm in some embodiments) corresponding to the location of the laser on the PIC 106.

While the edges and fillet of the adhesive underfill 109 are outside the die shadow of the PIC 106 in the illustrated embodiment, in other embodiments the adhesive underfill 109 may be contained exclusively under the die (e.g., for KOZ improvement).

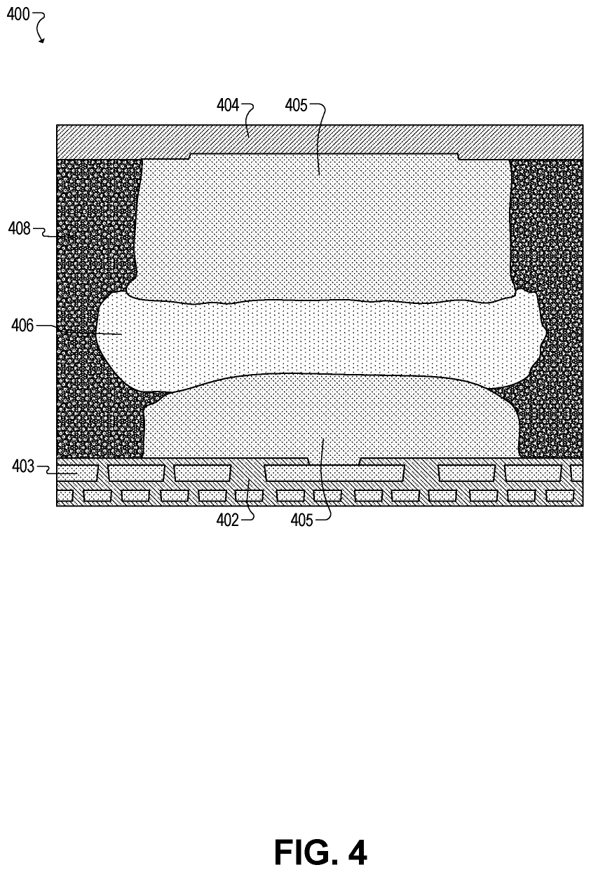

FIG. 4 illustrates an example cross-section image 400 of a joint between two dies 402, 404 bonded together using thermoset adhesive 408. In some embodiments, for example, the dies 402, 404 may be an electronic integrated circuit (EIC) 402 and a photonic integrated circuit (PIC) 404 bonded together using the process described in connection with FIGS. 2A-E.

In the illustrated example, a portion near the surface of each die 402, 404 is shown, including conductive traces 403 embedded in the EIC die 402, along with a pair of conductive bumps 405 (e.g., copper microbumps) on the surfaces of the respective dies 402, 404. The pair of conductive bumps 405 are joined together with solder 406, thus forming an electrical connection or “joint” between the dies 402, 404. While only a single joint is shown in the illustrated example, the dies 402, 404 may be electrically connected via numerous joints.

Further, the space between the dies 402, 404 around the joint is filled with thermoset adhesive 408 (e.g., using the process of FIGS. 2A-E), which bonds the dies 402, 404 together and forms a buffer between them to protect the joint. In the illustrated example, the adhesive material 408 is a non-conductive paste (NCP) made of an acrylic polymer with silica filler (e.g., sub-micron silica particles), where the filler is represented by the small circular particles within the adhesive 408. The filler may be added to the acrylic polymer to modify the mechanical properties of the adhesive 408, such as the coefficient of thermal expansion (CTE), to provide optimal performance for bonding the dies 402, 404 together and protecting their joints.

However, in other areas of the dies 402, 404 (not shown), the space between the dies may not contain any underfill or other materials. For example, in some embodiments, the space between the dies 402, 404 may be selectively filled with the adhesive underfill 408 in areas where the joints are located, but not in restricted areas near optical components that need to remain unobstructed, such as the PIC laser and groove keep out zones (KOZs) (not shown).

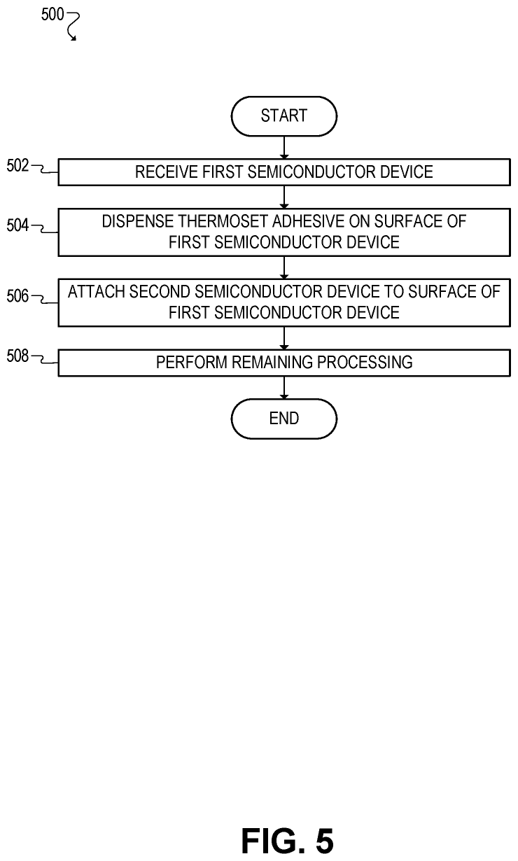

FIG. 5 illustrates a flowchart 500 for a pre-applied underfill and chip attach packaging process using thermoset adhesive. In some embodiments, for example, the illustrated process flow may be used to attach an integrated circuit (IC) die or package to another semiconductor device—such as another IC die or package, package substrate, printed circuit board, or combination thereof—using pre-applied underfill. The illustrated process flow can be used to apply underfill to the entire area under the IC die or only select areas while keeping underfill out of other restricted areas. In some embodiments, for example, the process flow may be used to form optical packages with restricted areas or keep out zones (KOZs), such as IC packages 100, 600 of FIGS. 1A-B, 6A-B. However, it will be appreciated in light of the present disclosure that the illustrated process flow is only one example methodology for arriving at the example integrated circuit packages shown and described throughout this disclosure.

The process flow begins at block 502 by receiving a first semiconductor device, such as an IC die or package, package substrate, printed circuit board, or combination thereof (e.g., an IC die electrically coupled to a package substrate, an IC package electrically coupled to a circuit board). In some embodiments, for example, the first semiconductor device may include an electronic integrated circuit (EIC) or a photonic integrated circuit (PIC) electrically coupled to a package substrate.

The process flow then proceeds to block 504 to dispense a thermoset adhesive on a surface of the first semiconductor device. In some embodiments, for example, the thermoset adhesive may be dispensed in one or more locations, patterns, and/or shot weights on the surface of the first semiconductor device to achieve the requisite underfill footprint when a second semiconductor device is subsequently attached and compresses the adhesive.

For example, the thermoset adhesive may be dispensed in a uniform pattern designed to fill the entire area between the first and second semiconductor devices, or the thermoset adhesive may be dispensed in a non-uniform pattern designed to selectively fill some areas between the first and second semiconductor devices while keeping the adhesive out of other restricted areas. The pattern(s) may include one or more lines, dots, squares, rectangles, circles, star-shaped patterns, or any other suitable combination of shapes and patterns designed to fill the requisite area(s) with the adhesive.

The adhesive may be made of any suitable material(s) that are adhesive, viscous, and non-conductive. In some embodiments, for example, the adhesive may be a thermoset adhesive that cures when exposed to heat or radiation (e.g., thermal or ultraviolet (UV) curing), such as a thermosetting polymer. For example, the adhesive may be a thermoset non-conducive paste (NCP) made of an organic polymer and optionally an inorganic filler, such as an acrylic polymer with silica filler (SiO₂). Thus, in some embodiments, the adhesive may be made of material(s) that include elements such as, without limitation, carbon (C), hydrogen (H), oxygen (O), silicon (Si), and combinations thereof. In other embodiments, however, the adhesive may be made of material(s) that are curable using other (e.g., non-thermal) curing processes.

After dispensing the thermoset adhesive on the first semiconductor device, the process flow proceeds to block 506 to attach a second semiconductor device—such as an IC die or package—to the surface of the first semiconductor device.

In some embodiments, for example, the second semiconductor device is attached and electrically coupled to the surface of the first semiconductor device using thermocompression bonding (TCB). For example, the second semiconductor device is placed onto the surface of the first semiconductor device with their respective conductive contacts aligned (e.g., with solder between the conductive contacts in some embodiments), the devices are compressed together with high pressure, and the adhesive is cured using heat (e.g., at high temperature) or radiation (e.g., UV light exposure). In this manner, the patterned thermoset adhesive on the surface of the first semiconductor device is compressed, which causes it to spread or flow into the intended underfill areas between the first and second semiconductor devices, while any restricted areas remain free of underfill. As a result, the compressed adhesive has an irregular geometry that either fully or partially fills the area between the first and second semiconductor devices, depending on the design rules and the dispensed pattern. Further, the high temperature and/or radiation causes the compressed adhesive to cure, which bonds the first and second semiconductor devices together, and also causes the formation of joints, or electrical connections, between the conductive contacts on the first and second semiconductor devices.

In some embodiments, for example, the first and second semiconductor devices may respectively include an EIC and a PIC (or vice versa), which are designed to be electrically coupled via conductive contacts on their respective surfaces. Further, the PIC may be designed to emit laser beams through a particular area between the PIC and the EIC, and the PIC may also include one or more features, such as V-grooves, to optically couple the PIC with one or more optical fibers (e.g., either directly or indirectly via an optical coupler). Accordingly, certain restricted areas or KOZs may be defined to ensure that the laser and groove areas of the PIC remain free of obstructions such as underfill. As a result, a thermoset adhesive may be dispensed on the surface of the EIC (or the PIC) in one or more patterns that, when compressed, cause the adhesive to fill area(s) between the EIC and PIC where the conductive contacts are located, without filling restricted area(s) between the EIC and PIC where the laser and V-grooves are located. In this manner, some area(s) between the EIC and PIC are filled with adhesive while other area(s) are not.

The process flow then proceeds to block 508 to perform any remaining processing, such as attaching additional optical components (e.g., optical connectors, fibers) and/or electrical components (e.g., IC dies or packages containing processors, XPUs, memory, etc.).

In some embodiments, for example, one or more optical fibers may be optically coupled with the PIC, either directly (e.g., via adhesive) or indirectly (e.g., via an optical connector). For example, the fibers may be attached directly to the V-grooves in the PIC using an adhesive. Alternatively, an optical ferrule may be attached to the fibers, an optical coupler may be attached to the V-grooves in the PIC, and the optical ferrule and optical coupler may be designed to interface with each other (e.g., by plugging one into the other).

Further, in some embodiments, the first and/or second semiconductor devices may be electrically coupled to one or more additional IC dies, packages, or substrates. In some embodiments, for example, the first and/or second semiconductor devices may be electrically coupled to a package substrate, and another IC die or package may also be electrically coupled to the same package substrate. In some embodiments, the IC die or package may include processing circuitry, memory circuitry, storage circuitry, or communication circuitry. Further, in some embodiments, the resulting IC package may be electrically coupled to a circuit board and/or incorporated into an electronic device (e.g., with other electronic components).

At this point, the process flow may be complete. In some embodiments, however, the process flow may restart and/or certain blocks may be repeated. For example, in some embodiments, the process flow may restart at block 502 to continue forming integrated circuit packages using pre-applied thermoset adhesive.

FIGS. 6A-B illustrate an example embodiment of an optical package 600 in accordance with certain embodiments. In particular, cross-section and plan views of optical package 600 are respectively shown in FIGS. 6A and 6B. In some embodiments, optical package 600 may be formed using the selective underfill process with pre-applied thermoset adhesive described throughout this disclosure. In the illustrated embodiment, for example, optical package 600 contains thermoset adhesive underfill 611 below the photonic integrated circuits (PICs) 604 where the conductive contacts 605 reside, but not in the restricted laser keep out zone (KOZ) 613.

In the illustrated embodiment, the optical package 600 includes an XPU 608 along with multiple electronic integrated circuits (EICs) 606 and corresponding photonic integrated circuits (PICs) 604 on a package substrate 602. The XPU 608 and EICs 606 are attached to the top surface of the package substrate 602, and the PICs 604 are attached to the top surface of corresponding EICs 606.

The package substrate 602 includes conductive contacts 601 (e.g., balls, pads) on the bottom surface, which serve as a second level interconnect (SLI) to a next-level component, such as a printed circuit board (e.g., a motherboard) and/or another integrated circuit package (not shown). The package substrate 602 also includes conductive traces (not shown) patterned in the substrate to provide power and input/output (I/O) to the respective components in package 600 (e.g., XPU 608, EICs 606, PICs 604).

The XPU 608 is electrically coupled to the package substrate 602 via conductive contacts 609 (e.g., bumps/micro-bumps), which serve as a first level interconnect (FLI) for the XPU 608. The XPU 608 is also electrically coupled to the EICs 606 via bridges 603 embedded in the substrate 602 (e.g., embedded multi-die interconnect bridges (EMIB)). In this manner, the XPU 608 can communicate optically using the PICs 604 associated with the EICs 606.

The XPU 608 generally represents any integrated circuit component included in the optical package 600 to enable the component to communicate using fiber optics. For example, the XPU 608 may include any type or combination of processing units or other computing components, including, but not limited to, microcontrollers, microprocessors, processor cores, central processing units (CPUs), graphics processing units (GPUS), vision processing units (VPUs), tensor processing units (TPUs), application-specific integrated circuits (ASICs), field-programmable gate arrays (FPGAs), input/output (I/O) controllers and devices, switches, network interface controllers (NICs), persistent storage devices, and memory.

The EICs 606 are used to control the PICs 604 and may include components such as drivers, transimpedance amplifiers (TIA), carrier phase recovery (CPR), clock/data recovery (CDR), serializer/deserializer, equalizer, sampler, and so forth. The EICs 606 are electrically coupled to the package substrate 602 via conductive contacts 607 (e.g., bumps/micro-bumps), and the EICs 606 are further electrically coupled to the XPU 608 via the bridges 603 embedded in the substrate 602.

The PICs 604 are used to send and/or receive optical signals via fiber arrays 630 on behalf of the XPU 608. Each PIC 604 includes components and circuitry for sending and receiving optical signals, such as laser diodes (LD)/modulators (LD-MOD) (e.g., for transmitting optical signals), photodiodes (PD) (e.g., for receiving optical signals), waveguides, optical couplers, collimation/refocusing lenses, reflection mirrors, and so forth.

Each PIC 604 is controlled by an associated EIC 606 and is electrically coupled to the top surface of the EIC 606 via conductive contacts 605 (e.g., bumps/micro-bumps).

Each PIC 604 is also attached to an optical coupler 610, which is designed to mate with a pluggable optical ferrule 620 attached to an array of fibers 630. In this manner, each PIC 604 is optically coupled to an associated fiber array 630 via the mated optical coupler 610 and optical ferrule 620. In some embodiments, the optical coupler 610 and ferrule 620 may be made of glass.

The optical coupler 610, which may also be referred to as an optical interposer, routes optical signals (e.g., light) to and from the PIC 604 via waveguides (not shown). The optical coupler 610 includes the waveguides (not shown) to route the optical signals and may also include other optical and/or electrical routing features, such as through-glass vias, reflection mirrors, and so forth.

The optical ferrule 620 includes an array of holes/waveguides (not shown), which are attached to a bundle of optical (e.g., glass) fibers 630 referred to as a fiber array or fiber array unit (FAU). The fiber array 630 is used to send and receive optical signals to and from other components (not shown).

In some embodiments, the optical coupler 610 and optical ferrule 620 may include complementary mating and alignment features (e.g., mating protrusions and receptacles, pins and pin holes, grooves) to ensure they mate with each other with the requisite degree of alignment, as the fibers 630 in the ferrule 620 must be precisely aligned with the waveguides in the optical coupler 610. For example, when the optical ferrule 620 is plugged into to the optical coupler 610, their respective mating and alignment features engage, which causes the optical fibers 630 in the ferrule 620 to precisely align with the waveguides in the optical coupler 610. In this manner, the PIC 604 is optically coupled to the fiber array 630 via the mated optical coupler 610 and ferrule 620, which enables the PIC 604 to send and receive optical signals via the fiber array 630.

The other end of the fiber array 630 may be optically coupled to other components (not shown), such as other computing components that are part of the same device or system as optical package 600 (e.g., processors, XPUs, network interface controllers (NICs), storage, memory, I/O devices, other integrated circuits), an external device or system, a switch, another optical connector (e.g., a connector similar to optical coupler 610 and/or optical ferrule 620, a standard optical connector such as a mechanical transfer (MT) or multi-fiber push on (MPO) connector), a fiber cable, and so forth.

In some embodiments, the optical package 600 may be part of an electronic device or system, such as a mobile device, a wearable device, a computer, a server, a video playback device, a video game console, a display device, a camera, or an appliance. For example, the optical package 600 and various other electronic components may be electrically coupled to a circuit board within the electronic device.

It should be appreciated that optical package 600 is merely presented as an example. In other embodiments, certain components may be omitted, added, rearranged, modified, or combined. For example, embodiments may include any number, combination, or arrangement of PICs and EICs (e.g., for higher bandwidth and/or redundancy), optical connectors, optical couplers, optical ferrules, optical interposers, fibers, bridges, XPUs or other computing components, substrates, surface cavities in the substrate, conductive contacts, conductive traces, vias, integrated circuit packages, and so forth.

### EXAMPLE INTEGRATED CIRCUIT EMBODIMENTS

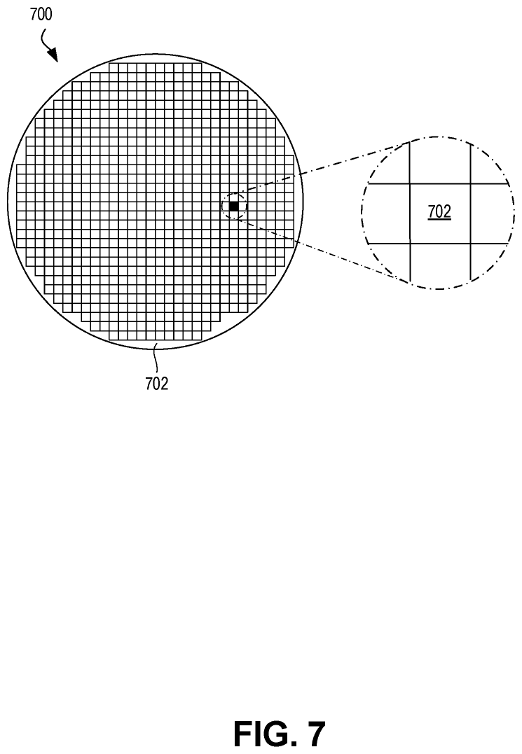

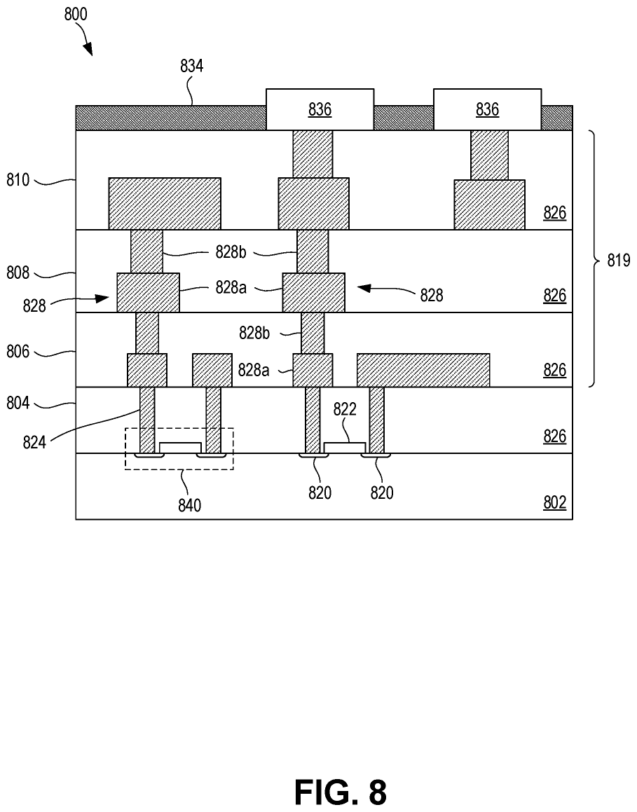

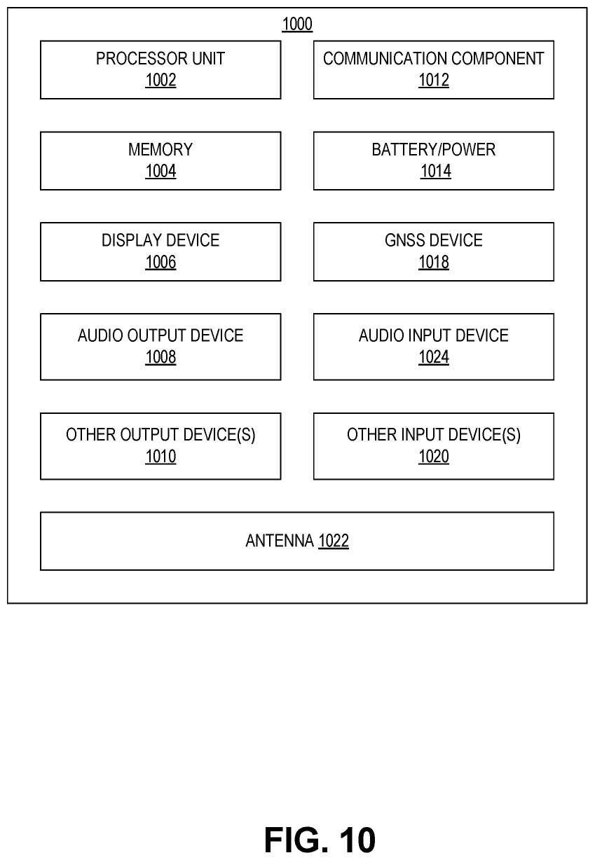

FIG. 7 is a top view of a wafer 700 and dies 702 that may be included in any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may be any of the dies disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1002 of FIG. 10) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include others of the dies, and the wafer 700 is subsequently singulated.

FIG. 8 is a cross-sectional side view of an integrated circuit device 800 that may be included in any of the embodiments disclosed herein (e.g., in any of the dies, such as EIC 104, 606, PIC 106, 604, XPU 608). One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components. The conductive contacts 836 may serve as any of the conductive contacts described throughout this disclosure.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836. These additional conductive contacts may serve as any of the conductive contacts described throughout this disclosure.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. These additional conductive contacts may serve as any of the conductive contacts described throughout this disclosure. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

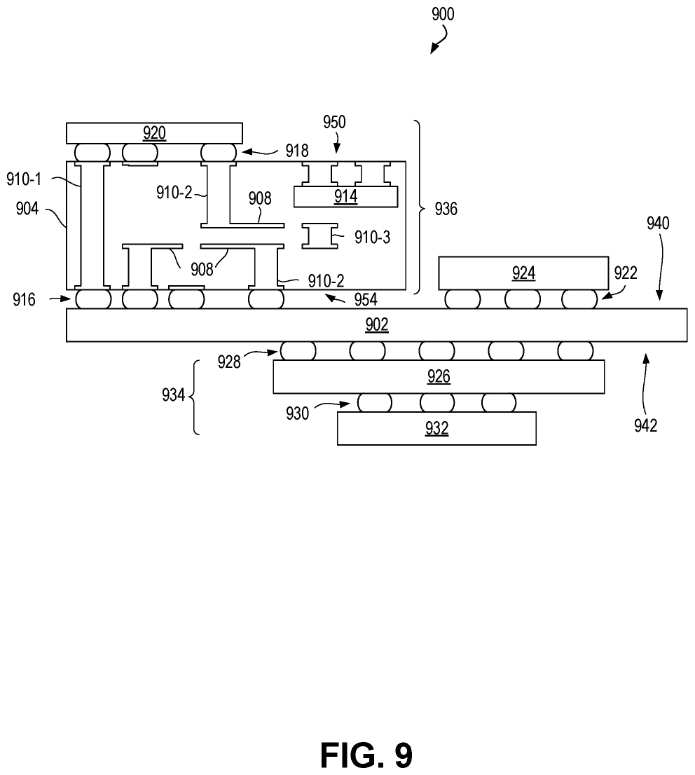

FIG. 9 is a cross-sectional side view of an integrated circuit device assembly 900 that may include any of the embodiments disclosed herein (e.g., optical package 100, 600). In some embodiments, the integrated circuit device assembly 900 may be a microelectronic assembly. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942. Any of the integrated circuit components discussed below with reference to the integrated circuit device assembly 900 may take the form of any suitable ones of the embodiments of the microelectronic assemblies disclosed herein.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 916 may serve as the coupling components illustrated or described for any of the substrate assembly or substrate assembly components described herein, as appropriate.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electronic device 1000 that may include one or more of the embodiments disclosed herein. For example, any suitable ones of the components of the electronic device 1000 may include one or more of the optical packages 100, 600, integrated circuit device assemblies 900, integrated circuit components 920, integrated circuit devices 800, or integrated circuit dies 702 disclosed herein. In some embodiments, for example, the electronic device 1000 and/or its respective components (e.g., processor units 1002, input/output (I/O) devices 1010, 1020, communication components 1012, memory 1004) may include an integrated circuit package (e.g., an optical package) with pre-applied thermoset adhesive underfill according to any of the embodiments described herein. A number of components are illustrated in FIG. 10 as included in the electronic device 1000, but any one or more of these components may be omitted or duplicated, as suitable for the application. In some embodiments, some or all of the components included in the electronic device 1000 may be attached to one or more motherboards mainboards, or system boards. In some embodiments, one or more of these components are fabricated onto a single system-on-a-chip (SoC) die.

Additionally, in various embodiments, the electronic device 1000 may not include one or more of the components illustrated in FIG. 10, but the electronic device 1000 may include interface circuitry for coupling to the one or more components. For example, the electronic device 1000 may not include a display device 1006, but may include display device interface circuitry (e.g., a connector and driver circuitry) to which a display device 1006 may be coupled. In another set of examples, the electronic device 1000 may not include an audio input device 1024 or an audio output device 1008, but may include audio input or output device interface circuitry (e.g., connectors and supporting circuitry) to which an audio input device 1024 or audio output device 1008 may be coupled.

The electronic device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electronic device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (cDRAM) or spin transfer torque magnetic random access memory (STT-MRAM).

In some embodiments, the electronic device 1000 can comprise one or more processor units 1002 that are heterogeneous or asymmetric to another processor unit 1002 in the electronic device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electronic device 1000.

In some embodiments, the electronic device 1000 may include a communication component 1012 (e.g., one or more communication components). For example, the communication component 1012 can manage wireless communications for the transfer of data to and from the electronic device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electronic device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electronic device 1000 may include battery/power circuitry 1014. The battery/power circuitry 1014 may include one or more energy storage devices (e.g., batteries or capacitors) and/or circuitry for coupling components of the electronic device 1000 to an energy source separate from the electronic device 1000 (e.g., AC line power).

The electronic device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electronic device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electronic device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electronic device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electronic device 1000 based on information received from one or more GNSS satellites, as known in the art.

The electronic device 1000 may include other output device(s) 1010 (or corresponding interface circuitry, as discussed above). Examples of the other output device(s) 1010 may include an audio codec, a video codec, a printer, a wired or wireless transmitter for providing information to other devices, or an additional storage device.

The electronic device 1000 may include other input device(s) 1020 (or corresponding interface circuitry, as discussed above). Examples of the other input device(s) 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electronic device 1000 may have any desired form factor, such as a hand-held or mobile electronic device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electronic device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electronic device or an embedded computing system (e.g., computing systems that are part of a vehicle, smart home appliance, consumer electronics product or equipment, manufacturing equipment). In some embodiments, the electronic device 1000 may be any other electrical or electronic device that processes data. In some embodiments, the electronic device 1000 may comprise multiple discrete physical components. Given the range of devices that the electronic device 1000 can be manifested as in various embodiments, in some embodiments, the electronic device 1000 can be referred to as a computing device or a computing system.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an integrated circuit package, comprising: a package substrate; a first integrated circuit (IC) die electrically coupled to the package substrate; a second IC die electrically coupled to the first IC die, wherein the second IC die is above or below the first IC die; and a thermoset adhesive that partially fills an area between the first IC die and the second IC die.

Example 2 includes the integrated circuit package of Example 1, wherein: the first IC die comprises an electronic integrated circuit (EIC); and the second IC die comprises a photonic integrated circuit (PIC).

Example 3 includes the integrated circuit package of Example 2, wherein: the PIC is to send or receive optical signals; and the EIC is to control the PIC.

Example 4 includes the integrated circuit package of any of Examples 2-3, wherein the area between the first IC die and the second IC die comprises: one or more first areas between the EIC and the PIC, wherein the one or more first areas are filled with the thermoset adhesive; and one or more second areas between the EIC and the PIC, wherein the one or more second areas are not filled with the thermoset adhesive.

Example 5 includes the integrated circuit package of Example 4, wherein the EIC and the PIC are electrically coupled via a plurality of conductive contacts, wherein the plurality of conductive contacts are located in at least one of the one or more first areas filled with the thermoset adhesive.

Example 6 includes the integrated circuit package of any of Examples 4-5, wherein the PIC is to emit laser beams through at least one of the one or more second areas that are not filled with the thermoset adhesive.

Example 7 includes the integrated circuit package of any of Examples 4-6, wherein the PIC comprises one or more grooves to optically couple the PIC with one or more optical fibers, wherein the one or more grooves are located in at least one of the one or more second areas that are not filled with the thermoset adhesive.

Example 8 includes the integrated circuit package of Example 7, further comprising the one or more optical fibers.

Example 9 includes the integrated circuit package of any of Examples 1-8, further comprising a third IC die electrically coupled to the package substrate, wherein the third IC die comprises a microcontroller, a microprocessor, a central processing unit, a graphics processing unit, a vision processing unit, a tensor processing unit, an application-specific integrated circuit, a field-programmable gate array, an input/output device, a switch, a network interface controller, a memory device, or a persistent storage device.

Example 10 includes the integrated circuit package of any of Examples 1-9, wherein the thermoset adhesive comprises an acrylic polymer and a silica filler.

Example 11 includes the integrated circuit package of any of Examples 1-10, wherein the thermoset adhesive has an irregular geometry.

Example 12 includes an electronic device, comprising: a circuit board; and an integrated circuit package coupled to the circuit board, wherein the integrated circuit package comprises: a photonic integrated circuit (PIC) to send or receive optical signals; an electronic integrated circuit (EIC) to control the PIC, wherein the EIC is above or below the PIC, and wherein the EIC is electrically coupled to the PIC; and a thermoset adhesive that partially fills an area between the EIC and the PIC.

Example 13 includes the electronic device of Example 12, wherein the area between the EIC and the PIC comprises: a first area filled with the thermoset adhesive, wherein the EIC and the PIC are electrically coupled via conductive contacts located in the first area; and a second area that is not filled with the thermoset adhesive, wherein the PIC is to emit laser beams through the second area.

Example 14 includes the electronic device of any of Examples 12-13, wherein the integrated circuit package further comprises an integrated circuit die, wherein the integrated circuit die comprises processing circuitry, memory circuitry, storage circuitry, or communication circuitry.

Example 15 includes the electronic device of any of Examples 12-14, wherein the electronic device is a mobile device, a wearable device, a computer, a server, a video playback device, a video game console, a display device, a camera, or an appliance.

Example 16 includes a method, comprising: receiving a first semiconductor device; dispensing a thermoset adhesive on the first semiconductor device, wherein the thermoset adhesive is dispensed in one or more patterns on a surface of the first semiconductor device; and after dispensing the thermoset adhesive on the first semiconductor device, attaching a second semiconductor device to the surface of the first semiconductor device.

Example 17 includes the method of Example 16, wherein the one or more patterns comprise one or more lines or dots.

Example 18 includes the method of any of Examples 16-17, wherein attaching the second semiconductor device to the surface of the first semiconductor device comprises: attaching the second semiconductor device to the surface of the first semiconductor device using thermocompression bonding.

Example 19 includes the method of any of Examples 16-18, wherein: the first semiconductor device comprises an electronic integrated circuit (EIC); and the second semiconductor device comprises a photonic integrated circuit (PIC).

Example 20 includes the method of any of Examples 16-18, wherein: the first semiconductor device comprises a package substrate; and the second semiconductor device comprises an integrated circuit die.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for case of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “between”, “adjacent”, “to”, and “on” as used herein may refer to a relative position of one layer or component with respect to other layers or components. For example, one layer “over” or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and/or metallization structures. The substrate may mechanically support and electrically couple one or more IC dies on a single platform, with encapsulation of the one or more IC dies by a moldable dielectric material. The substrate generally comprises solder bumps as bonding interconnects on both sides. One side of the substrate, generally referred to as the “die side”, may comprise solder bumps for chip or die bonding. The opposite side of the substrate, generally referred to as the “land side”, may comprise solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

1. An integrated circuit package, comprising:
a package substrate;
a first integrated circuit (IC) die electrically coupled to the package substrate;
a second IC die electrically coupled to the first IC die, wherein the second IC die is above or below the first IC die; and
a thermoset adhesive that partially fills an area between the first IC die and the second IC die.

2. The integrated circuit package of claim 1, wherein:
the first IC die comprises an electronic integrated circuit (EIC); and
the second IC die comprises a photonic integrated circuit (PIC).

3. The integrated circuit package of claim 2, wherein:
the PIC is to send or receive optical signals; and
the EIC is to control the PIC.

4. The integrated circuit package of claim 2, wherein the area between the first IC die and the second IC die comprises:
one or more first areas between the EIC and the PIC, wherein the one or more first areas are filled with the thermoset adhesive; and
one or more second areas between the EIC and the PIC, wherein the one or more second areas are not filled with the thermoset adhesive.

5. The integrated circuit package of claim 4, wherein the EIC and the PIC are electrically coupled via a plurality of conductive contacts, wherein the plurality of conductive contacts are located in at least one of the one or more first areas filled with the thermoset adhesive.

6. The integrated circuit package of claim 4, wherein the PIC is to emit laser beams through at least one of the one or more second areas that are not filled with the thermoset adhesive.

7. The integrated circuit package of claim 4, wherein the PIC comprises one or more grooves to optically couple the PIC with one or more optical fibers, wherein the one or more grooves are located in at least one of the one or more second areas that are not filled with the thermoset adhesive.

8. The integrated circuit package of claim 7, further comprising the one or more optical fibers.

9. The integrated circuit package of claim 2, further comprising a third IC die electrically coupled to the package substrate, wherein the third IC die comprises a microcontroller, a microprocessor, a central processing unit, a graphics processing unit, a vision processing unit, a tensor processing unit, an application-specific integrated circuit, a field-programmable gate array, an input/output device, a switch, a network interface controller, a memory device, or a persistent storage device.

10. The integrated circuit package of claim 1, wherein the thermoset adhesive comprises an acrylic polymer and a silica filler.

11. The integrated circuit package of claim 1, wherein the thermoset adhesive has an irregular geometry.

12. An electronic device, comprising:
a circuit board; and
an integrated circuit package coupled to the circuit board, wherein the integrated circuit package comprises:
a photonic integrated circuit (PIC) to send or receive optical signals;
an electronic integrated circuit (EIC) to control the PIC, wherein the EIC is above or below the PIC, and wherein the EIC is electrically coupled to the PIC; and
a thermoset adhesive that partially fills an area between the EIC and the PIC.

13. The electronic device of claim 12, wherein the area between the EIC and the PIC comprises:
a first area filled with the thermoset adhesive, wherein the EIC and the PIC are electrically coupled via conductive contacts located in the first area; and
a second area that is not filled with the thermoset adhesive, wherein the PIC is to emit laser beams through the second area.

14. The electronic device of claim 12, wherein the integrated circuit package further comprises an integrated circuit die, wherein the integrated circuit die comprises processing circuitry, memory circuitry, storage circuitry, or communication circuitry.

15. The electronic device of claim 12, wherein the electronic device is a mobile device, a wearable device, a computer, a server, a video playback device, a video game console, a display device, a camera, or an appliance.

16. A method, comprising:
receiving a first semiconductor device;
dispensing a thermoset adhesive on the first semiconductor device, wherein the thermoset adhesive is dispensed in one or more patterns on a surface of the first semiconductor device; and
after dispensing the thermoset adhesive on the first semiconductor device, attaching a second semiconductor device to the surface of the first semiconductor device.

17. The method of claim 16, wherein the one or more patterns comprise one or more lines or dots.

18. The method of claim 16, wherein attaching the second semiconductor device to the surface of the first semiconductor device comprises:
attaching the second semiconductor device to the surface of the first semiconductor device using thermocompression bonding.

19. The method of claim 16, wherein:
the first semiconductor device comprises an electronic integrated circuit (EIC); and
the second semiconductor device comprises a photonic integrated circuit (PIC).

20. The method of claim 16, wherein:
the first semiconductor device comprises a package substrate; and
the second semiconductor device comprises an integrated circuit die.
